(19) United States
(12) Patent Application Publication
(10) Pub. No.: US 2010/0263716 A1
(43) Pub. Date: Oct. 21, 2010

(54) SOLAR CELL MODULE

(75) Inventor: Noriyuki KITAO, Susono-shi (JP)

Correspondence Address: GIFFORD, KRASS, SPRINKLE,ANDERSON & CITKOWSKI, P.C, PO BOX 7021, TROY, MI, 48007-7021, US

(73) Assignee: Toyota Jidosha Kabushiki Kaisha, Toyota-Shi (JP)

(21) Appl. No.: 12/712,496

(22) Filed: Feb. 25, 2010

(30) Foreign Application Priority Data
Apr. 21, 2009 (JP) JP2009-103105

(51) Int. Cl. H01L 31/00

(52) U.S. Cl. 136/252

(57) ABSTRACT

A solar cell module of the present invention is provided with a reflector that reflects incident light to a solar cell, and a reflecting surface of the reflector is in a concave-convex shape. The reflector is constructed with a diffuse reflective material that diffusely reflects light. Some of sunlight that enters the solar cell module hits a front surface of the solar cell, and the rest passes through a gap between the solar cells and then enters the diffuse reflector. The sunlight that enters the diffuse reflector is diffusely reflected, and thus an amount of light that enters a back surface of the solar cell increases. Thereby, the solar cell module can increase power generation efficiency.

### INCORPORATION BY REFERENCE

The disclosure of Japanese Patent Application No. 2009-103105 filed on Apr. 21, 2009 including the specification, drawings and abstract is incorporated herein by reference in its entirety.

### BACKGROUND OF THE INVENTION

1. Field of the Invention

The present invention relates to a light gathering solar cell module that includes a reflector.

2. Description of the Related Art

Japanese Patent Application Publication No. 2001-119054 (JP-A-2001-119054) describes a solar cell module that includes a plurality of bifacial solar cells arranged separately in a transparent member made of ethylene-vinyl acetate resin (EVA resin). A front surface of the transparent member is provided with a glass transparent member, and a back surface of the transparent member is provided with an aluminum or stainless substrate (reflector). The reflector that specularly reflects the light is formed in the surface of the substrate that abuts on the transparent member and has a continuous V shape cross section. Some of the sunlight that enters through the transparent plate of the module directly hits the front surface of the solar cell. The rest of the sunlight that passes through a gap between the neighboring solar cells and reaches the substrate is reflected by the reflecting surface onto the back surface of the solar cell. In the solar cell module with such a structure, the sunlight that enters the gaps between the neighboring solar cells may be efficiently used, so that the power generation efficiency is improved.

However, in the solar cell module described above, depending on the angle of incidence, the light that is specularly reflected by the reflecting surface of the substrate may again pass through the gap between the solar cells and travel to the front surface side of the module. In this case, the indirect light that reflected by the reflecting surface of the substrate escapes from the module without hitting the solar cell, which creates a problem that power generation efficiency worsens.

### SUMMARY OF THE INVENTION

The present invention provides a solar cell module that utilizes sunlight more efficiently and that has improved power generation efficiency.

An aspect of the present invention relates to a solar cell module. A solar cell module includes: a solar cell; a reflector that reflects incident light toward the solar cell. The reflector has a corrugated reflecting surface and is made of a diffuse reflective material. Because the light is diffusely reflected by the reflector in the above structure, the amount of reflected light that enters the solar cell may be increased and the power generation efficiency improved in comparison with structures that utilize the a reflector that specularly reflect the light.

According to the present invention, the solar cell module that can utilize sunlight more efficiently and that has improved power generation efficiency is provided.

### BRIEF DESCRIPTION OF THE DRAWINGS

The foregoing and further features and advantages of the invention will become apparent from the following description of example embodiments with reference to the accompanying drawings, wherein like numerals are used to represent like elements and wherein:

FIG. 1 is a cross sectional view that shows a solar cell module according to an embodiment of the present invention;

FIG. 2A to FIG. 2D are cross sectional views that show examples of the structure of a diffuse reflector;

FIG. 3 is an exploded perspective view of lamination structure of the solar cell module;

FIG. 4A and FIG. 4B are cross sectional views that show the relationship between a module width and a detector width;

FIG. 5 is a graph that shows an output relationship between a specular reflection module and a diffuse reflection module;

FIG. 6 is a graph that shows an output relationship between the specular reflection module and the diffuse refection module, in which a reflector's shape is modified to increase light gathering capability;

FIG. 7 is a cross sectional view of the mono-facial solar cell module;

FIG. 8 is a cross sectional view of the solar cell module according to the first embodiment;

FIG. 9 is a graph that shows the output relationship between a specular reflection module and a diffuse reflection module according to the first embodiment; and

FIG. 10 is a graph that shows the light-use efficiency relationship between a specular reflection module and a diffuse reflection module according to the first embodiment.

### DETAILED DESCRIPTION OF EMBODIMENTS

Hereinafter, embodiments of the solar cell module according to the present invention are described in detail with reference to accompanying drawings.

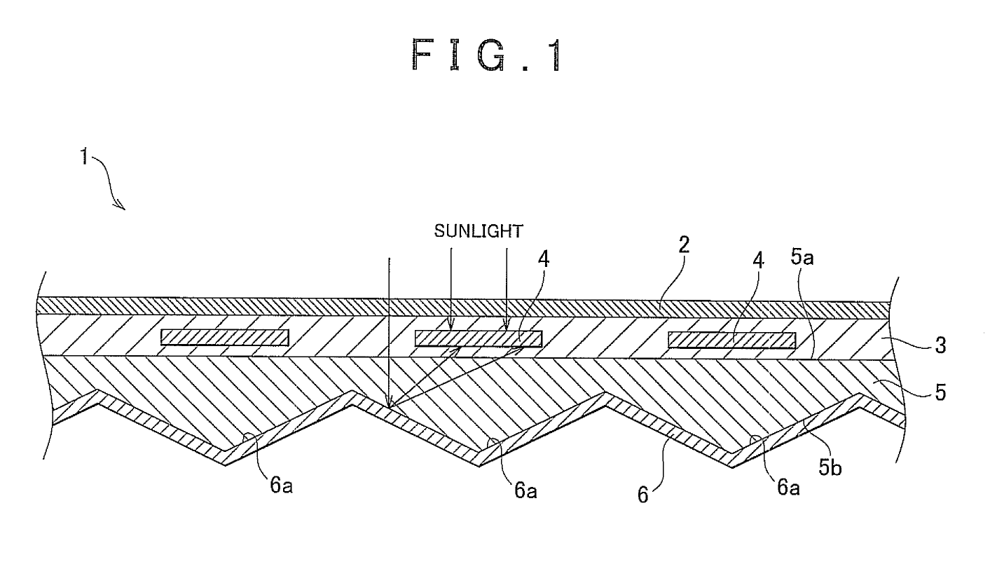

A light gathering solar cell module 1, shown in FIG. 1, which is applied to in a vehicle is set in the outdoors where direct sunlight is available, and generates photovoltaic power efficiently. The solar cell module 1 includes a front surface substrate 2 that allows the incidence of the sunlight and that has generally uniform thickness. In an encapsulant 3 that is fixed to the front substrate 2, solar cells 4 that are arranged in a matrix are encapsulated. EVA resin may be used as a sealing material of the encapsulant 3. The solar cell 4 used herein is a bifacial cell that can capture sunlight on both surfaces.

A back surface substrate 5 is fixed to a back surface of the encapsulant 3 so as to face the front substrate 2 arranged on a front side of the encapsulant 3. The back surface substrate 5 includes: a flat surface 5a that is fixed to the encapsulant 3; and a V-shaped surface 5b that faces the flat surface 5. The corrugations of the V-shaped surface 5b are arranged continuously, and each corrugation is generally identical. The back surface substrate 5 is made of a transparent member, which may be for example glass, a transparent plastic (such as polycarbonate and acrylic), EVA resin, etc. The back surface substrate 5 may be formed through processing such as grinding, polishing, injection, vacuum heat press, or direct rolling, etc.

A diffuse reflector 6, in which generally identical V-shaped surfaces 6a are arranged, is fixed to the V-shaped surface 5b of the back surface substrate 5. The corrugations of the back surface substrate 5 and those of the diffuse reflector 6 correspond to each other, and the both members contact each other. The diffuse reflector 6 may be made of various materials such as a multi-layer film of polyester resin or a substrate in which a highly reflective plastic film is attached to a metal substrate, as long as the material enhances the diffuse reflection of the reflector. Because the diffuse reflector 6 includes a multi-layered structure or single-layered structure made of resin, the diffuse reflector 6 is easily formed by the press bending process. Also, material and processing costs are reduced in comparison with the case where the reflecting surface is formed by depositing aluminum or silver on the metal surface.

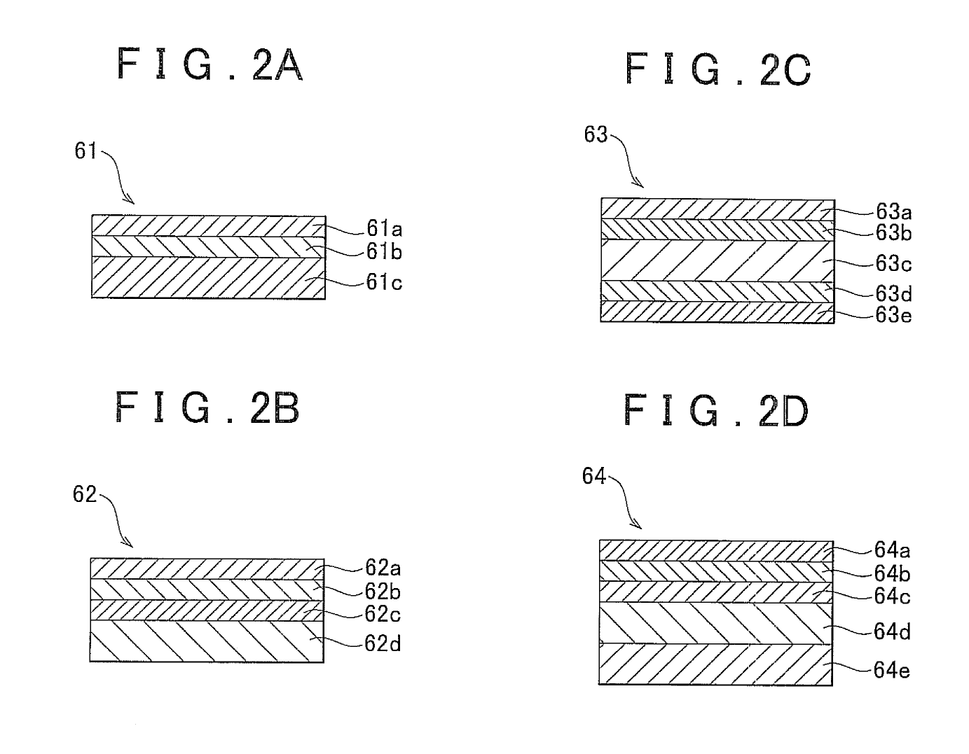

FIG. 2A to FIG. 2D show diffuse reflectors 61 to 64, each of which has multi-layered structure with different materials. An upper surface of the diffuse reflectors 61 to 64 shown in the drawings is fixed to the back surface substrate 5.

As shown in FIG. 2A, the diffuse reflector 61 is constructed by laminating a protective layer 61a, polyester resin layer 61b, and a cover layer 61c in this order. Similarly, as shown in FIG. 2B, the diffuse reflector 62 is constructed by laminating a protective layer 62a, PET (polyethylene terephthalate) layer 62b, a polyester resin layer 62c, a cover layer 62d.

As shown in FIG. 2C, a diffuse reflector 63 is constructed by laminating a plastic layer 63a, a specially treated layer 63b, a metal layer 63c, a special surface treated layer 63d, and a plastic layer 63e. As shown in FIG. 2D, a diffuse reflector 64 is constructed by laminating a protective layer 64a, a PET layer 64b, a polyester resin layer 64c, a cover layer 64d, and a metal substrate 64e.

The protective layer may be formed from silicon dioxide. The metal layer and the metal substrate may be made of aluminum or stainless steel. The polyester layer and the plastic layer may be made from polyethylene terephthalate, polytrimethylene terephthalate, polybutylene terephthalate, polyethylene naphthalate, and polybutylene naphthalate. The cover layer may be made from a mixture of polyethylene terephthalate resin and titanium dioxide particles.

By forming the diffuse reflectors 61 to 64 as a multi-layered structure, the incident light is efficiently and diffusely reflected by interfacial reflection. A single-layer diffuse reflector 6 may be formed with, for example, one sheet of PET material.

Next, the method of manufacturing the solar cell module will be described.

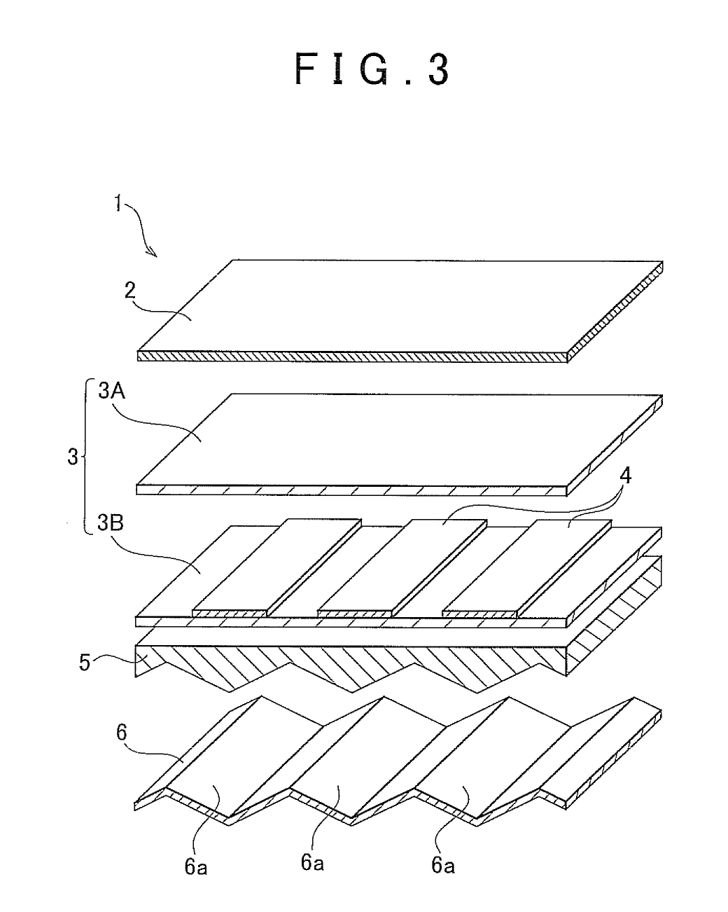

As shown in FIG. 3, the solar cell module 1 is formed by laminating, from the front surface side, the front substrate 2, the encapsulant sheet 3A, the solar cell 4, the encapsulant sheet 3B, the back surface substrate 5, and the diffuse reflector 6 in this order. The encapsulant sheets 3A and 3B are made of EVA resin, and the solar cell 4 is interposed between the encapsulant sheet 3A and the encapsulant sheet 3B.

In this state, laminating process is performed so as to integrate each member to make the solar cell module 1. The laminating process is carried out under the condition of, for example, vacuuming for 15 minutes and pressing for 25 minutes, and at temperature of 145° C.

When the back surface substrate 5 that is made of EVA resin is press-formed, a sheet of the diffuse reflector 6 may be set on the die, and then the lamination of the diffuse reflector 6 and the EVA resin that is placed above the diffuse reflector 6 may be heat-pressed. By the above method, an integrated back surface member of the back surface substrate 5 and the diffuse reflector 6 are fabricated. Thus, the manufacturing processes and cost may be further reduced.

If the back surface substrate 5 is made of a material other than EVA resin, a transparent bonding layer (such as EVA resin) is interposed between the back surface substrate 5 and the diffuse reflector 6 so as to connect them together.

With the solar cell module 1 constructed as described above, the light is diffusely reflected by the diffuse reflector 6, and an increased amount of reflected light may be introduced to the solar cell 4, as shown in FIG. 1.

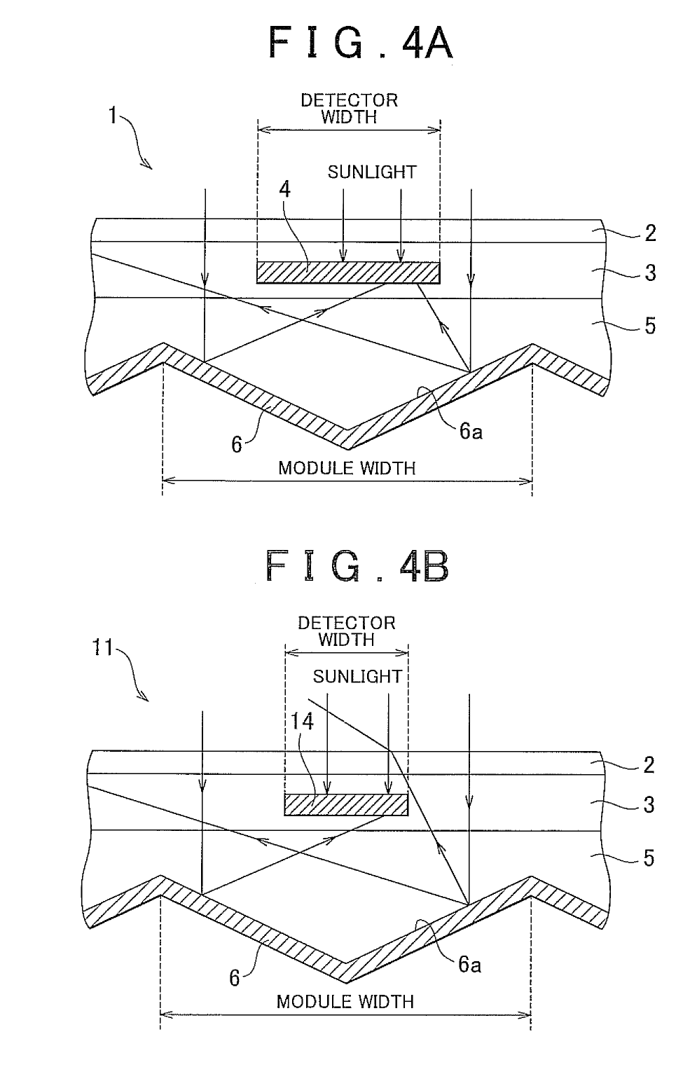

The relationship between the ratio between the detector width and the module width of the solar cell 4 and the output of the solar cell module will be described below. FIG. 4A shows the cross section of the solar cell module 1 in which the ratio between the detector width and the module width (detector width/module width) is ½. FIG. 4B shows a cross section of a solar cell module 11 in which the ratio between the detector width and the module width is ⅓.

Here, the detector width is the width of the detection area of the solar cells 4 and 14. The module width is a width of the single V-shaped surface 6a that faces the solar cells 4 and 14. The single V-shaped surface 6a is a reflecting surface that contributes to light incidence towards the opposite solar cells 4 and 14. In FIG. 4A and 4B, hatching is provided only to the solar cells 4 and 14 and the diffuse reflector 6 in order to indicate the light path clearly. Reflectance of the diffuse reflector 6 in FIG. 4A and 4B is theoretically 90%.

As shown in FIG. 4A, the sunlight, which enters the solar module 1, hits the front surface of the solar cell 4, and the indirect light, which is diffusely reflected by the diffuse reflector 6, hits the back surface of the solar cell 4. As shown in FIG. 4B, when the detector width of the solar cell 14 is narrow, the amount of the light entering the front surface of the solar cell 14, less than that of the solar cell module 1 in FIG. 4A. Moreover, the amount of the indirect light entering the back surface of the solar cell 14 after being diffusely reflected by the diffuse reflector 6, is also small. In this way, the ratio between the detector width and the module width affects the output of the solar cell module.

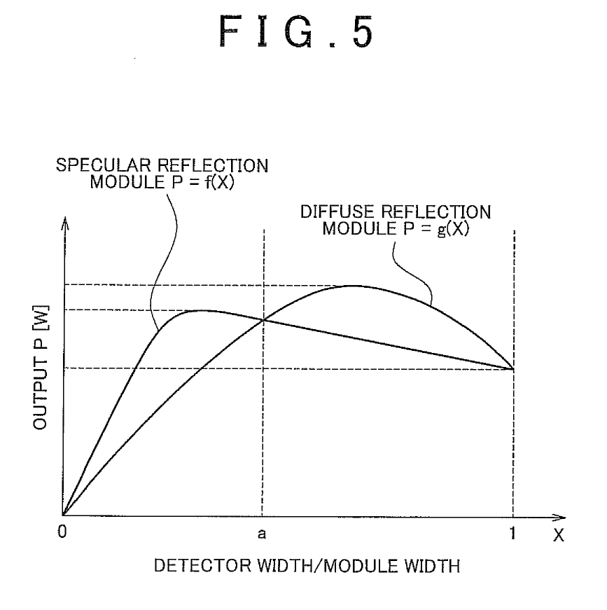

As shown in FIG. 4A, when the single V-shaped surface 6a is the reflecting surface that contributes to the light incidence to the solar cell 4, the output P of the solar cell module 1 varies according to the ratio X between the detector width and module width as shown by the graph “diffuse reflection module P=g(X)” in FIG. 5. As shown in FIG. 5, the output P reaches a maximum value when the ratio X is slightly larger than 0.5.

Here, in FIG. 5, the output P of the solar cell module using the specular reflector is indicated by “specular reflection module P=f(X).” The solar cell module shown in FIG. 5 is provided with the specular reflector instead of the diffuse reflector 6 of the solar cell module 1 shown in FIG. 4A. The shape of the reflector is the same as the diffuse reflector 6. The reflectance of the reflector is 90%.

In this case, the output P of the specular reflection module reaches the maximum value before the diffuse reflection module P=g(X) and when the ratio X is close to the origin 0. The maximum output value P of the diffuse reflection module g(X) is larger than the maximum output value P of the specular reflection module f(X). The graphs of P=f(X) and P=g(X) cross each other when the ratio X is “0”, “a”, and “1”. When the ratio X is larger than “a”, the solar cell module 1 with the diffuse reflector 6 produces higher output. The graphs P=f(X) and P=g(X) shown in FIG. 5, whose parameters are for example the shape of the reflecting surface and the width of the detector, may be established through optical simulation.

The following equations are specific examples of the functions P=f(X) and P=g(X) that are used in the optical simulation: g(X)=1.40X−X²; f(X)=9.97X⁶−28.94X⁵+27.57X⁴ −5.56X³−5.89X²+3.18X; and P=f(X)=g(X), where the values of X that satisfy these equations are 0, a=approximately 0.4, and 1.

As described above, if the reflector has a continuous and generally equal V shape, and the ratio X between the detector width and the module width is larger than or equal to “a”, the photovoltaic efficiency of the solar cell module with the diffuse reflector is higher than that of the module with the specular reflector.

Next, the output of the solar cell module that is provided with a diffuse reflector that is shaped to further increase the light gathering capacity of the diffuse reflector 6 will be described. “The shape to increase light gathering capacity” means that the single V shaped surface 6a shown in FIG. 1 is formed in the W shape or the concave shape, for example.

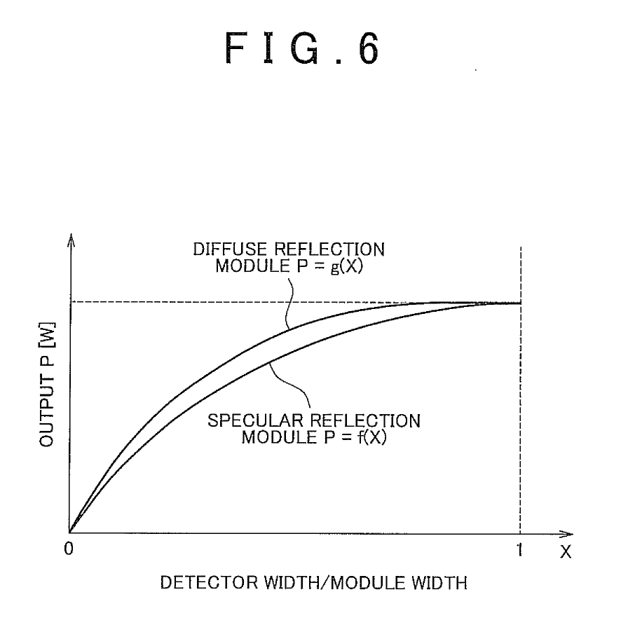

The output P of the solar cell module shaped to increase light gathering capacity increases along with increases of the ratio X as shown by the graph P=g(X) of the diffuse reflection module in FIG. 6. Also, the output P of the solar cell module provided with the specular reflector increases along with the increase of the ratio X as shown by the graph P=f(X) of the specular reflection module in FIG. 6. However, the graphs P=f(X) and P=g(X) do not cross each other except at X=0 and X=1. The solar cell module with the diffuse reflector always produces the higher output.

Accordingly, if the solutions that satisfy P=g(X)=f(X) are only X=0 and X=1, regardless of the detector width, the high efficiency photovoltaic solar cell module can be obtained by using the diffuse reflector as a reflecting surface.

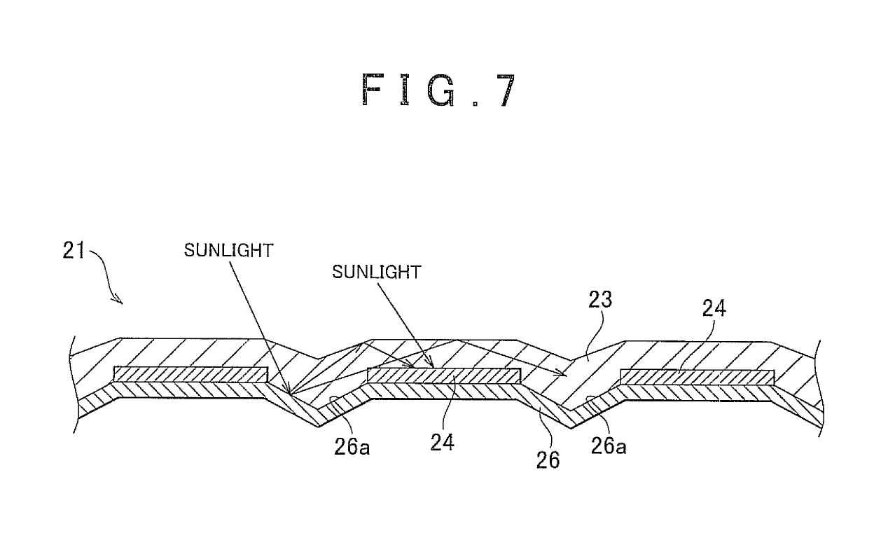

In the above embodiments, a solar cell module that is provided with bifacial solar cells, which receive light on two surfaces, has been described. However, as shown in FIG. 7, a diffuse reflector 26 may be used with a mono-facial solar cell module 21 in which the solar cells receive light on only one surface. In this case, a solar cell 24 is arranged on the diffuse reflector 26, and an encapsulant 23 is arranged on the diffuse reflector 26 to cover the solar cell 24. V-shaped depressions are formed in the diffuse reflector 26 between the solar cells 24 to diffusely reflect light.

Among the sunlight that enters the solar cell module 21, the indirect light that is diffusely reflected by the V-shaped surface 26a travels to the front surface of the encapsulant 23. The indirect light is then interfacially reflected by the surface of the encapsulant 23, and again travels to the solar cell 24. Because the light is diffusely reflected by the V-shaped surface 26a, it increases the amount of the light that enters the solar cell 24 among the light interfacially reflected by the surface of the sealing part 23, and thereby increases the power generation efficiency of the solar cell module 21. In this way, the power generation efficiency of a mono-facial solar cell module may also be increased by using a diffuse reflector.

Next, the solar cell module output and the light-use efficiency at various incident light angles of bifacial solar cell modules that respectively incorporate a diffuse reflector and a specular reflector will be compared.

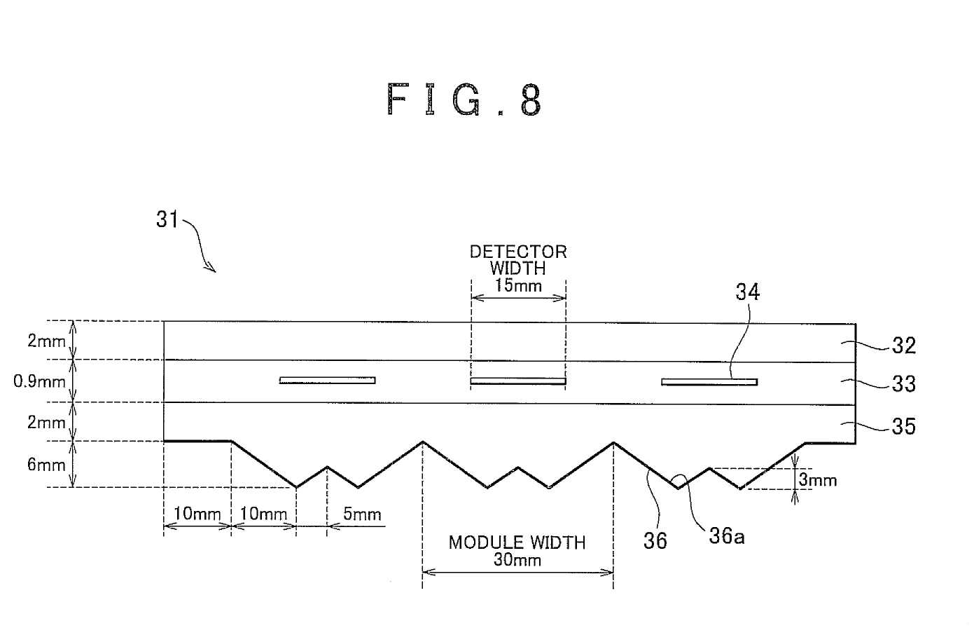

As show in FIG. 8, in the solar cell module 31, the thickness of a front substrate 32 is 2 mm, the thickness of an encapsulant 33 is 0.9 mm, and the diffuse reflector 36 has a continuous W-shaped surface 36a. The W-shaped surface 36a and the back surface substrate 35 are fabricated as the dimension shown in the drawing. The detector width of a solar cell 34 is 15 mm, and the module width is 30 mm. The reflectance of the reflector 36 is 90%. FIG. 8 is a schematic view of the solar cell module, and the thickness and the like of each member are different from the actual proportion.

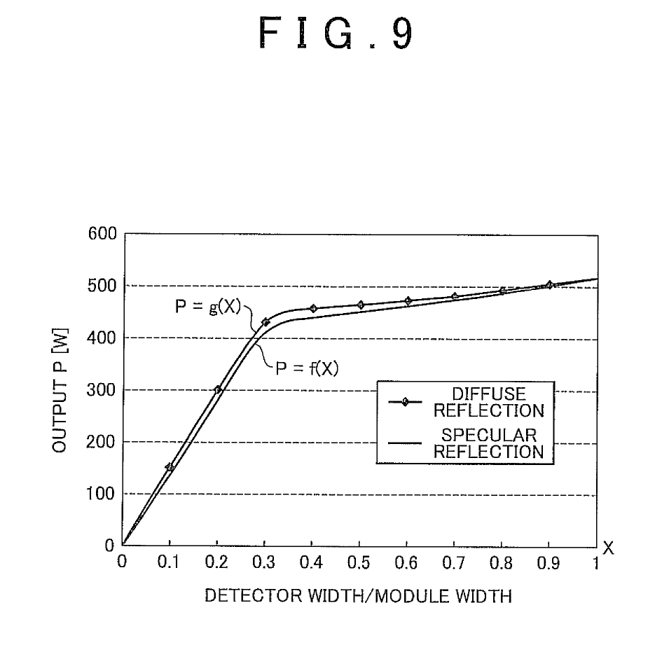

The solar cell module 31 that uses a diffuse reflector 36 shows the output P as represented by P=g(X) in FIG. 9, where the ratio of the detector width to the module width is indicated by X. However, in a comparable solar cell module that instead uses a reflector that specularly reflects light with 90% reflectance, the output P as represented by the graph P=f(X) in FIG. 9. As shown in FIG. 9, the solutions that satisfy P=f(X)=g(X) are only X=0 and X=1. In this case, it is apparent that the solar cell module 31 with a diffuse reflector 36 always produces higher output than the solar cell module 31 with a specular reflector.

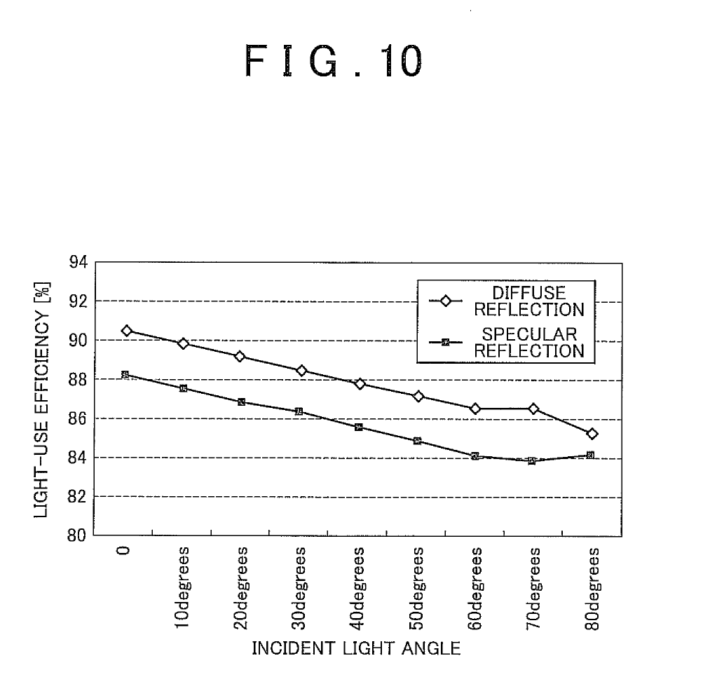

FIG. 10 shows the light-use efficiency at different incident light angles with respect to the solar cell. The incident light angle shows the degrees from the vertical line that extends above the solar cell.

As the incident light angle changes from the vertical line that extends above the solar cell, the light-use efficiency decreases for both the solar cell module 31 with the diffuse reflector 36 and the solar cell module with the specular reflector. However, for any incident angle, the solar cell module 31 with the diffuse reflector 36 exhibits the light-use efficiency about 2% higher than a solar cell module with a specular reflector. Therefore, use of a diffuse reflector instead of a specular reflector improves the light-use efficiency at all incident light angles.

What is claimed is:

1. A solar cell module comprising:
a solar cell;
a reflector that reflects incident light toward the solar cell, wherein the reflector has corrugated reflecting surface, wherein
the reflector is made of diffuse reflective material.

2. The solar cell module according to claim 1, wherein:
the reflector has a continuous V-shaped surface in which each V shape has generally the same shape; and
a ratio between a detector width of the solar cell and a width of the single V-shaped surface that faces the solar cell is 0.4 to 1.

3. The solar cell module according to claim 1, wherein the reflector is multi-layered.

4. The solar cell module according to claim 3, wherein the reflector is constructed with a protective layer, a polyester resin layer, and a cover layer that are laminated in this order.

5. The solar cell module according to claim 3, wherein the reflector is constructed with a protective layer, a polyethylene terephthalate layer, a polyester resin layer, and a cover layer that are laminated in this order.

6. The solar cell module according to claim 3, wherein the reflector is constructed with a first plastic layer, a first special surface treated layer, a metal layer, a second special surface treated layer, and a second plastic layer that are laminated in this order.

7. The solar cell module according to claim 3, wherein the reflector is constructed with a protective layer, a polyethylene terephthalate layer, a polyester resin layer, a cover layer, and a metal substrate that are laminated in this order.

8. The solar cell module according to claim 4, wherein the cover layer is a mixture of polyethylene terephthalate resin and titanium dioxide particles.

9. The solar cell module according to claim 5, wherein the cover layer is a mixture of polyethylene terephthalate resin and titanium dioxide particles.

10. The solar cell module according to claim 7, wherein the cover layer is a mixture of polyethylene terephthalate resin and titanium dioxide particles.
